(19) United States
(12) Patent Application Publication
(10) Pub. No.: US 2026/0161090 A1
(43) Pub. Date: Jun. 11, 2026

(54) UNDERLAYER WITH ENTRAPPED EXTREME ULTRAVIOLET (EUV) ABSORPTION ELEMENT

(71) Applicant: Applied Materials, Inc., Santa Clara, CA (US)

(72) Inventors: RUDY WOJTECKI, East Garrison, CA (US); SIVANANDHA KANAKASABAPATHY, Pleasanton, CA (US)

(21) Appl. No.: 19/402,422

(22) Filed: Nov. 26, 2025

Related U.S. Application Data
(60) Provisional application No. 63/729,426, filed on Dec. 8, 2024.

(51) Int. Cl. G03F 7/26; G03F 7/00; G03F 7/038; H01L 21/027

(52) U.S. Cl. CPC G03F 7/265; G03F 7/0385; G03F 7/70033; H10P 76/2041

(57) ABSTRACT

Embodiments described herein relate to a method of treating an underlayer for a photoresist, where the underlayer includes reactive organic moieties. In an embodiment, the method includes exposing the underlayer to an environment including a species that has a molar absorption coefficient for extreme ultraviolet (EUV) radiation that is 0.5×10⁷ cm²/mol or higher, where the species diffuses into the underlayer. In an embodiment, the method further includes cross-linking the underlayer, where the species are entrapped in the underlayer.

### CROSS-REFERENCE TO RELATED APPLICATIONS

This application claims the benefit of U.S. Provisional Application No. 63/729,426, filed on Dec. 8, 2024, the entire contents of which are hereby incorporated by reference herein.

### BACKGROUND

### 1) Field

Embodiments relate to the field of semiconductor manufacturing and, in particular, to underlayers with entrapped species to enhance EUV absorption.

### 2) Description of Related Art

Extreme ultraviolet (EUV) photoresists allow for the continued scaling to smaller features that are patterned on a semiconductor substrate. In an EUV lithography process, EUV radiation is selectively applied to regions of the photoresist layer in order to generate a solubility switch that enables the formation of a latent image within the photoresist layer. The latent image corresponds to the portions of the photoresist layer that have undergone the solubility switch as a result of a chemical reaction that is induced by the EUV exposure. After the latent image is produced within the photoresist layer, a developing process may be used in order to generate a pattern in the photoresist layer.

However, existing EUV resist materials suffer from poor absorption of EUV photons. This results in the need for long exposure times. As such, the throughput for EUV lithography is low, which also results in EUV lithography being an expensive process.

### SUMMARY

Embodiments described herein relate to a method of treating an underlayer for a photoresist, where the underlayer includes reactive organic moieties. In an embodiment, the method includes exposing the underlayer to an environment including a species that has a molar absorption coefficient for extreme ultraviolet (EUV) radiation that is 0.5×10⁷ cm²/mol or higher, where the species diffuses into the underlayer. In an embodiment, the method further includes cross-linking the underlayer, where the species are entrapped in the underlayer.

Embodiments described herein relate to a method for processing a stack including a photoresist layer over an underlayer, where the underlayer includes reactive organic moieties. In an embodiment, the method includes exposing the underlayer to an environment including a species that has a molar absorption coefficient for extreme ultraviolet (EUV) radiation that is 0.5×10⁷ cm²/mol or higher, where the species diffuses into the underlayer. In an embodiment, the method further includes cross-linking the underlayer, where the species is entrapped in the underlayer. In an embodiment, the method further includes depositing the photoresist layer over the underlayer.

Embodiments described herein relate to a method for treating an underlayer for a photoresist, where the underlayer includes reactive organic moieties. In an embodiment, the method includes exposing the underlayer to an environment including a gas including one or more of xenon, SF₆, C₄F₈, or an iodo-comprising compound (e.g., iodomethane or iodoethane), where a pressure of the gas is over 1.0 atmospheres, and where the gas diffuses into the underlayer. In an embodiment, the method further includes cross-linking the underlayer, where the gas is entrapped in the underlayer.

### BRIEF DESCRIPTION OF THE DRAWINGS

FIG. 1A is a cross-sectional illustration of a substrate with an underlayer over the substrate, in accordance with an embodiment.

FIG. 1B is a schematic illustration of carbon chains in the underlayer, in accordance with an embodiment.

FIG. 1C is a cross-sectional illustration of the underlayer during exposure to an inert gas that includes elements with high extreme ultraviolet (EUV) absorption properties, in accordance with an embodiment.

FIG. 1D is a schematic illustration of the carbon chains with elements of the inert gas diffused within the carbon chains, in accordance with an embodiment.

FIG. 1E is a cross-sectional illustration of the underlayer during a treatment that cross-links the carbon chains to entrap the elements of the inert gas within the underlayer, in accordance with an embodiment.

FIG. 1F is a schematic illustration of cross-linked carbon chains that entrap elements of the inert gas, in accordance with an embodiment.

FIG. 1G is a cross-sectional illustration of a resist layer deposited over the underlayer, in accordance with an embodiment.

FIG. 1H is a cross-sectional illustration of the resist layer after being exposed with EUV radiation, in accordance with an embodiment.

FIG. 1I is a cross-sectional illustration of the resist layer after being developed, in accordance with an embodiment.

FIG. 1J is a cross-sectional illustration of the resist layer after a patter in the resist layer is transferred into the underlayer, in accordance with an embodiment.

FIG. 2 is a flow diagram depicting a process for treating an underlayer in order to entrap elements that have high EUV absorption properties, in accordance with an embodiment.

FIG. 3 illustrates a block diagram of an exemplary computer system that may be used in conjunction with a processing tool, in accordance with an embodiment.

### DETAILED DESCRIPTION

Embodiments described herein include underlayer materials for extreme ultraviolet (EUV) lithography that have been treated to incorporate entrapped elements that improve EUV absorption of the underlayer. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, resist layers used in deep ultraviolet (DUV) and/or extreme ultraviolet (EUV) lithography often suffer from poor absorption of the DUV and/or EUV radiation. As such, the chemical reaction driven by radiation absorption (e.g., the release of secondary electrons) is minimal. This results in the need for high doses of the radiation. Accordingly, throughput is low and the lithography process is expensive.

Some solutions may include the use of an underlayer below the resist layer. An underlayer may also be photosensitive in order to generate secondary electrons. The secondary electrons within the underlayer may diffuse up into the resist layer in order to participate in the solubility switch reaction. For example, species from the underlayer that are released upon exposure to EUV and/or DUV radiation may diffuse into the resist layer and interact with a quencher (in a CAR material), interact with a photoacid generator (in a CAR material), participate in a cross-linking reaction (in a MOR material), and/or the like. The solubility switch within the resist layer is used to form a latent image. The latent image can then be developed in order to form a pattern within the resist layer that can be transferred into underlying layers.

However, the underlayer also suffers from poor DUV and/or EUV absorption. Typically, the underlayer comprises carbon and hydrogen, which do not absorb EUV and/or DUV radiation well. Accordingly, some embodiments have proposed adding a species into the underlayer that has better radiation absorption properties. For example, the species may be one that has a molar absorption coefficient for extreme ultraviolet (EUV) radiation that is 0.5×10⁷ cm²/mol or better, 1.0×10⁷ cm²/mol or better, or 1.5×10⁷ cm²/mol or better. For example, the species may comprise one or more of xenon, SF₆, C₄F₈, or an iodo-comprising compound (e.g., iodomethane or iodoethane). However, good diffusion of the species into the underlayer is achievable when the underlayer comprises low molecular weight polymer chains that are not substantially cross-linked. Unfortunately, such materials do not retain the species after treatment. That is, a substantial amount (or even substantially all) of the species that were diffused into the underlayer may rapidly outgas from the underlayer after the underlayer is removed from a high pressure environment.

Accordingly, embodiments disclosed herein may include a treatment for the underlayer that allows for good diffusion of the species into the underlayer without the species subsequently outgassing after the treatment. For example, the diffusion of the species into the underlayer may occur when the underlayer is not substantially cross-linked. Thereafter, a treatment may be applied to the underlayer to initiate cross-linking while the underlayer is still in a high pressure environment.

The cross-linking may result in the diffused species being entrapped within the underlayer. That is, after being removed from the high pressure environment, the diffused species within the underlayer may not substantially outgas. In an embodiment, the treatment may be a thermal cross-linking treatment, a UV exposure cross-linking treatment, and/or a chemical cross-linking treatment. The cross-linking closes pathways out of the underlayer and makes it much more difficult for the diffused species to outgas from the underlayer. More generally, the process of introducing a good EUV absorbing species into the underlayer may comprise: 1) providing the underlayer in a high pressure environment; 2) providing xenon in the high pressure environment to allow diffusion of xenon into the underlayer; 3) cross-linking the underlayer; and 4) reducing the pressure of the environment back to atmospheric pressure.

In an embodiment, the species that are diffused into the underlayer are non-reactive species in a gas form at normal processing temperatures (e.g., less than approximately 200° C.). In a particular embodiment, a noble gas is used. Of the noble gasses, it has been shown that xenon has excellent photon absorption characteristics. That is, interactions between xenon and DUV and/or EUV radiation may result in the xenon emitting secondary electrons that can be used to drive solubility switch reactions in the overlying resist layer. Though, any high EUV and/or DUV absorbing species may be used, such as SF₆, C₄F₈, or an iodo-comprising compound (e.g., iodomethane or iodoethane).

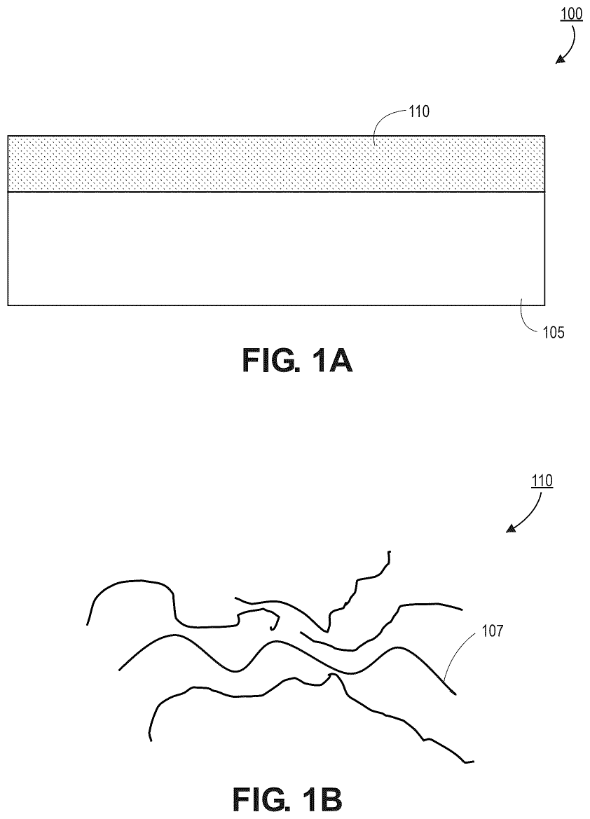

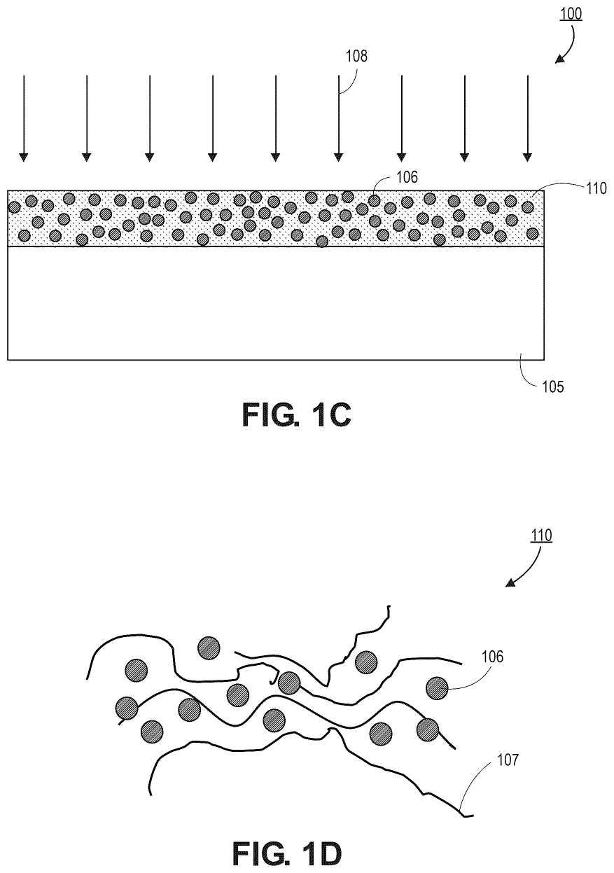

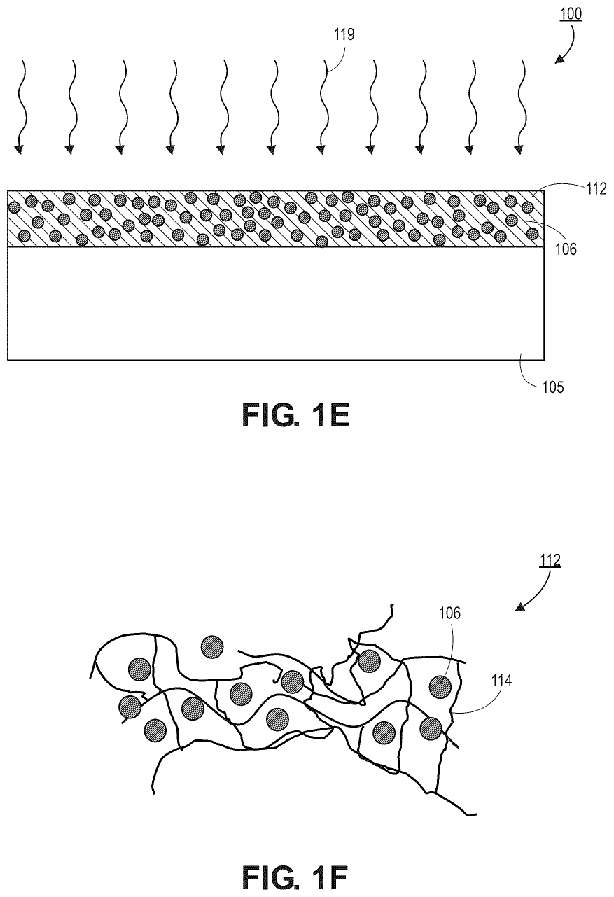

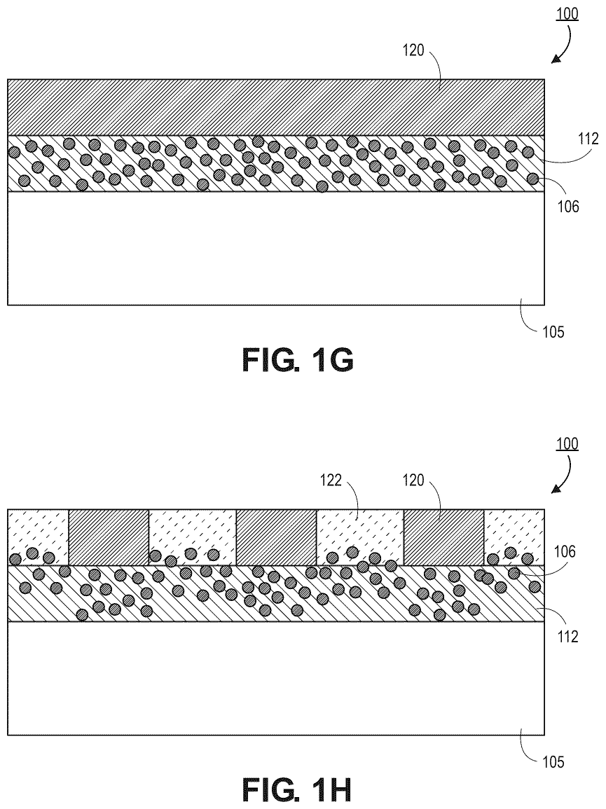

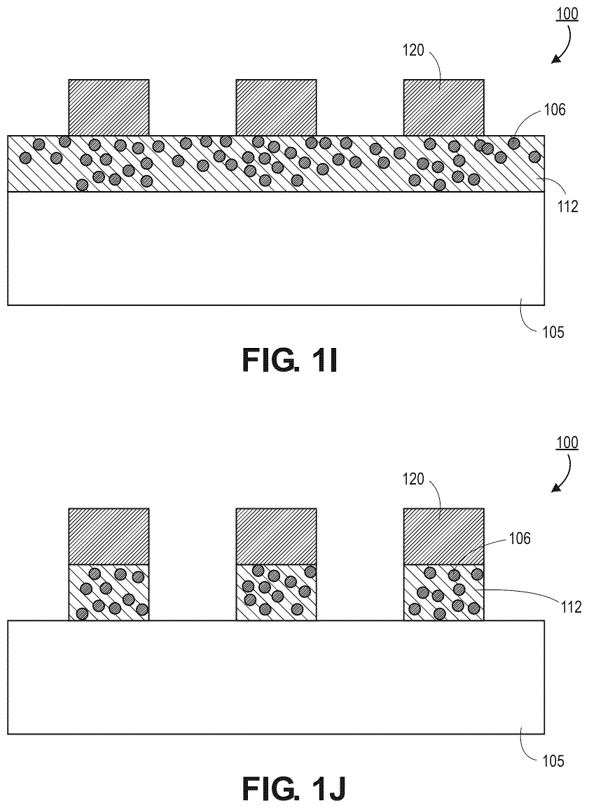

Referring now to FIGS. 1A-1J, a series of illustrations depicting a process for developing a patterning layer that comprises an underlayer and a resist layer is shown, in accordance with an embodiment. In an embodiment, the underlayer is treated in order to introduce species that have good photon absorption characteristics. As such, the exposure process can use a lower dose of EUV radiation (and/or DUV radiation). This increases the throughput of the lithography process and reduces the cost of the process overall.

Referring now to FIG. 1A, a cross-sectional illustration of a portion of a device 100 is shown, in accordance with an embodiment. In an embodiment, the device 100 may comprise a substrate 105. In an embodiment, the substrate 105 may comprise a semiconductor material, such as a silicon wafer, an oxide layer, a nitride layer, a metallic layer, or the like. In an embodiment, a patterning stack (not shown) may be provided over the substrate 105. For example, the patterning stack may include one or more layers suitable for transferring a pattern formed into the resist layer (not shown in FIG. 1A) into the underlying substrate 105. For example, the patterning stack may comprise multiple layers, such as a silicon hardmask layer, a carbon hardmask layer, an antireflective coating, and/or the like. In some embodiments, reference to the substrate 105 herein may also refer to the patterning stack between the substrate 105 and an underlayer 110.

In some embodiments, the material for the underlayer 110 may be a material that is compatible with patterning stack deposition processes and are structurally similar to existing polymer underlayer materials. In an embodiment, the underlayer 110 may comprise a material that is sensitive to EUV or DUV radiation in order to generate species (e.g., molecules, electrons, etc.) that can diffuse into the overlying resist layer (not shown in FIG. 1A) in order to participate in the solubility switch reaction. In an embodiment, the underlayer 110 may be deposited with a dry deposition process (e.g., chemical vapor deposition (CVD), atomic layer deposition (ALD), or the like).

In a particular embodiment, the underlayer 110 comprises carbon and hydrogen. For example, the carbon may be in the form of low molecular weight polymer chains and/or in the form of any suitable reactive organic moieties. The low molecular weight polymer chains or reactive organic moieties may be substantially free of cross-linking. For example, FIG. 1B is a schematic of polymer chains 107 that are present in the underlayer 110. As shown, each of the polymer chains 107 are substantially isolated from each other (e.g., without cross-linking). While shown as substantially linear carbon chains, it is to be appreciated that the polymer chains 107 may comprise branches in some embodiments. Additionally, reactive groups (not shown) may be provided at ends of the polymer chains 107 and/or along the length of the polymer chains 107.

In an embodiment, the underlayer 110 may comprise any suitable photosensitive material common in lithographic patterning processes. In one embodiment, the underlayer 110 may comprise an epoxy-based resin, such as a bisphenol A novolac epoxy, or the like. Other underlayer 110 materials may comprise poly(glycidyl methacrylate) or the like. More generally, the underlayer 110 may comprise C—X bonds, where X comprises one or more of H, F, Br, Cl, glycidyl, methacrylate, vinyl benzene, divinyl benzene, or disulfide in some embodiments. In an embodiment, the underlayer 110 may also comprise photoacid generators (PAGs) in some embodiments. PAGs may release an acid that drives the solubility switch in response to exposure to EUV and/or DUV radiation.

Referring now to FIG. 1C, a cross-sectional illustration of the portion of the device 100 after the underlayer 110 is exposed to an environment comprising a species 108 is shown, in accordance with an embodiment. The species 108 may comprise an element that has good absorption characteristics with respect to EUV and/or DUV radiation. That is, the species 108 may be efficient at absorbing EUV and/or DUV radiation and emitting secondary electrons. The secondary electrons may then be used to participate in the solubility switch reaction in order to provide a latent image in an overlying resist layer (not shown in FIG. 1C). In an embodiment, the species 108 may comprise a noble gas. For example, the species 108 may comprise a gas that comprises xenon. Though, in other embodiments, the species 108 may comprise other gasses with good EUV and/or DUV absorption properties, such as SF₆, C₄F₈, an iodo-comprising compound (e.g., iodomethane or iodoethane), or the like.

In an embodiment, the portion of the device 100 may be provided in a chamber where a pressure of the species 108 can be controlled. In order to increase the penetration of the diffused species 106 of the species 108 into the underlayer 110, the pressure of the species 108 may be relatively high. For example, the pressure of the species 108 may be approximately 1.0 atmospheres or higher, approximately 2.0 atmospheres or higher, or approximately 5.0 atmospheres or higher.

In an embodiment, diffused species 106 are better able to penetrate the underlayer 110 due to the composition and/or structure of the underlayer 110. For example, light molecular weight polymer chains 107 and/or reactive organic moieties that are not cross-linked provide pathways through the underlayer 110 to allow for better diffusion of the diffused species 106 into the underlayer 110 (e.g., compared to an underlayer 110 that is cross-linked).

In an embodiment, the exposure to the species 108 may be implemented for any desired duration, and at any desired temperature. The duration of the species 108 exposure may be for up to 30 seconds or more, up to 1.0 minute or more, up to 10 minutes or more, up to 30 minutes or more, or up to 1.0 hour or more. In the case of a thermally cross-linkable underlayer 110, a temperature of the underlayer 110 during the exposure to the species 108 may be below a temperature used to initiate the cross-linking reaction. In an embodiment, the temperature of the underlayer 110 during the exposure to the species 108 may be higher than a glass transition temperature of the underlayer 110 and below a cross-linking temperature of the underlayer 110. Bringing the underlayer 110 above the glass transition temperature may allow for improved diffusion of the diffused species 106 into the underlayer 110. For example, a temperature of the underlayer 110 during the exposure to the species 108 may be between approximately 50° C. and approximately 150° C. Though, other temperature ranges may also be used, depending on the material composition of the underlayer 110.

Referring now to FIG. 1D, a schematic illustration of the structure of the underlayer 110 after the diffusion of diffused species 106 into the polymer chain 107 structure is shown, in accordance with an embodiment. As shown, the diffused species 106 may be distributed throughout the network of polymer chains 107 and/or reactive organic moieties. At this point, the diffused species 106 are still free to move about the network of polymer chains 107 and/or reactive organic moieties since there is no (or minimal) cross-linking. If the device 100 were to be removed from the high pressure environment of the species 108, the diffused species 106 would readily outgas from the network of polymer chains 107 and/or reactive organic moieties.

Accordingly, embodiments disclosed herein include converting the underlayer 110 into a cross-linked structure in order to substantially entrap the diffused species 106. The cross-linking is initiated by the application of a treatment to the underlayer 110. In some embodiments, the treatment is applied while the device 100 is still exposed to the environment with the high pressure species 108. Though, in some instances the treatment may be applied shortly after (e.g., within 10 minutes, within 5 minutes, within 1 minute, or within 30 seconds) the device 100 is removed from the environment with the high pressure species 108.

Referring now to FIG. 1E, a cross-sectional illustration of the portion of the device 100 during a treatment 119 is shown, in accordance with an embodiment. In an embodiment, the treatment 119 may include the exposure of the underlayer 110 to any suitable radiation, thermal energy, chemical, and/or the like that results in the cross-linking of the underlayer 110 to form a cross-linked underlayer 112. In a particular embodiment, the treatment 119 may include exposure to UV radiation. Another embodiment may include a thermal anneal treatment. For example, a temperature of the underlayer 110 may be brought up to a temperature suitable for initiating a thermal cross-linking reaction. For example, a thermal anneal between approximately 150° C. and approximately 200° C. may be used in some embodiments. An exposure to a chemical may also be used to initiate the cross-linking reaction within the underlayer 110 to form the cross-linked underlayer 112.

In some embodiments, one or more pre-treatments may be applied to the underlayer 110 prior to the treatment 119 in order to improve the cross-linking reaction. For example, one or both of an amine or an alcohol may be used to pre-treat the underlayer 110. In such embodiments, the amine and/or the alcohol may work to open rings of the epoxy-based underlayer 110 in order to allow for cross-linking at lower temperatures, lower UV dosages, with a faster reaction rate, and/or the like. When such a pre-treatment is used, the pre-treatment May be implemented after diffusion of the diffused species 106 into the underlayer 110 and before the cross-linking reaction.

Referring now to FIG. 1F, a schematic illustration of the cross-linked underlayer 112 is shown, in accordance with an embodiment. As shown, the network of polymer chains 107 and/or reactive organic moieties has reacted in order to form a network of cross-linked polymer chains 114 (which may sometimes be referred to simply as the cross-linked underlayer). As can be appreciated, the diffused species 106 are now entrapped by the cross-linking between the polymer chains 114. This prevents (or mitigates) outgassing of the diffused species 106 from the cross-linked underlayer 112. As such, the device 100 may be removed from the high pressure environment for subsequent processing without significant outgassing of the diffused species 106 that are used to improve the generation of secondary electrons or other species used to drive the reaction to form a latent image in the overlying resist layer.

Referring now to FIG. 1G, a cross-sectional illustration of a portion of the device 100 after a resist layer 120 is applied over the cross-linked underlayer 112 is shown, in accordance with an embodiment. In an embodiment, the resist layer 120 may be a positive tone resist or a negative tone resist. The resist layer 120 may be a photosensitive material that reacts under exposure to EUV and/or DUV radiation to form a latent image in the resist layer 120 as a result of a localized solubility switch. In an embodiment, the resist layer 120 may be a chemically amplified resist (CAR), a metal-oxide resist (MOR), or the like.

With respect to MOR materials, the MOR composition may comprise metal-oxide clusters. The metal-oxide clusters may comprise one or more metal atoms and one or more oxygen atoms that are bonded together. In some embodiments, the metal within the metal-oxide clusters may comprise one or more of tin, indium, hafnium, zinc, zirconium, or any combination thereof). The MOR material may also comprise an organotin-oxide material, an organoindium-oxide material, or the like.

In an embodiment, the resist layer 120 may be deposited with any suitable deposition process. For example, the resist layer 120 may be applied with a wet process, such as one that comprises dispensing the resist layer 120 onto the cross-linked underlayer 112 and spinning the device 100 (e.g., using a spin-coating process). Other embodiments may include forming the resist layer over the cross-linked underlayer 112 using a dry deposition process, such as an atomic layer deposition (ALD) process, a chemical vapor deposition (CVD) process, or the like.

Referring now to FIG. 1H, a cross-sectional illustration of the device 100 after the resist layer 120 is selectively exposed to EUV and/or DUV radiation in order to form a latent image 122 is shown, in accordance with an embodiment. In an embodiment, the resist layer 120 may be selectively exposed with EUV and/or DUV radiation that is passed through a reticle, a mask, direct laser writing, or the like. In an embodiment, the latent image 122 is a region of the resist layer 120 that has undergone a solubility switch. For example, the latent image 122 may have undergone a deprotection reaction in order to make the latent image 122 soluble to a developing solution, or the latent image 122 may have undergone a cross-linking reaction in order to make the latent image resistant to a developing solution.

As shown in FIG. 1H, the exposure process may result in diffused species 106 from the cross-linked underlayer 112 diffusing into the overlying resist layer 120. For example, the diffused species 106 within the cross-linked underlayer 112 may react to the selective EUV and/or DUV radiation exposure in order to generate secondary electrons and/or other species that diffuse up into the latent image 122 area of the resist layer 120. This allows for faster reaction rates within the latent image 122 area. As such, the overall dose of the EUV and/or DUV radiation can be reduced while still producing the desired patterning properties.

In an embodiment, the pattern of the latent image 122 may be any suitable pattern. In one instance, the pattern may comprise lines (e.g., for the formation of traces in the substrate 105). In another instance, the pattern may comprise a pillars (e.g., to form via openings within the substrate 105). Though, it is to be appreciated that the pattern of the latent image 122 may comprise any combination of lines, pillars, and/or any other shaped feature.

Referring now to FIG. 1I, a cross-sectional illustration of a portion of the device 100 after the resist layer 120 is developed is shown, in accordance with an embodiment. In the illustrated embodiment, the developing process results in the removal of the exposed region of the resist layer 120 (i.e., the latent image 122). Though, in other embodiments the resist layer 120 may be of an opposite tone, and the unexposed region of the resist layer 120 may be removed while the latent image 122 remains. In an embodiment, the developing process may be a wet process that exposes the resist layer 120 to a wet chemistry in order to etch away a portion of the resist layer 120.

Referring now to FIG. 1J, a cross-sectional illustration of a portion of the device 100 after the pattern in the resist layer 120 is transferred into the cross-linked underlayer 112 is shown, in accordance with an embodiment. In an embodiment, the pattern may be transferred into the cross-linked underlayer 112 with an etching process that uses the remaining portions of the resist layer 120 as a mask. For example, a wet or dry etching process may be used to transfer the pattern into the cross-linked underlayer 112.

After the cross-linked underlayer 112 is patterned, the pattern may be transferred into the underlaying substrate 105 with any suitable process. In one embodiment, the pattern may be transferred into a patterning stack (not visible in FIG. 1J) that is between the cross-linked underlayer 112 and the substrate 105. After the patterning stack is patterned, one or both of the resist layer 120 or the cross-linked underlayer 112 may be removed before the pattern is transferred into lower portions of the substrate 105 (e.g., silicon, metal layers, dielectric layers, etc.).

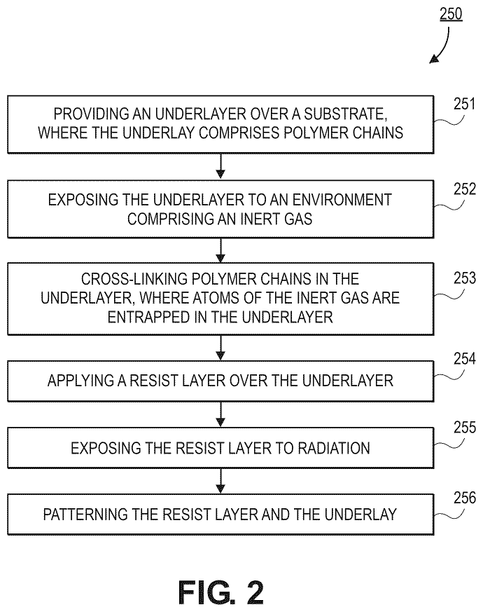

Referring now to FIG. 2, a flow diagram depicting a process 250 for treating an underlayer and patterning a substrate is shown, in accordance with an embodiment. In an embodiment, the process 250 may comprise operations similar to any of those described in greater detail herein with respect to FIGS. 1A-1J.

In an embodiment, the process 250 may begin with operation 251, which comprises providing an underlayer over a substrate. In an embodiment, the underlayer is a photosensitive material that comprises polymer chains and/or reactive organic moieties. A photosensitive material may refer to a material that is able to react in response to exposure to radiation, such as EUV radiation, DUV radiation, or the like. For example, one or more species within the photosensitive material may absorb EUV and/or DUV radiation and emit secondary electrons. In an embodiment, the underlayer may be similar to any of the underlayer materials described in greater detail herein. For example, the underlayer may comprise an epoxy-based underlayer material. In an embodiment, the underlayer may comprise polymer chains and/or reactive organic moieties that are substantially free from cross-links or comprise lightly cross-linked polymer chains.

In an embodiment, the process 250 may continue with operation 252, which comprises exposing the underlayer to an environment comprising an inert gas. In an embodiment, the inert gas may comprise atoms and/or species that are good absorbers of EUV and/or DUV radiation. In a particular embodiment, the inert gas may comprise a noble gas, such as xenon or the like. Though, other gasses such as SF₆, C₄F₈, an iodo-comprising compound (e.g., iodomethane or iodoethane) or the like may also be used. The environment may comprise a relatively high pressure of the inert gas. For example, a pressure of the inert gas may be approximately 1.0 atmospheres or more, approximately 2.0 atmospheres or more, or approximately 5.0 atmospheres or more. The exposure to the inert gas may be implemented for any suitable duration and at any suitable temperature, such as any of the temperatures and/or durations described in greater detail herein.

In an embodiment, the exposure to the environment comprising the good EUV and/or DUV absorbing species may allow for atoms and/or species to diffuse into the underlayer. The light cross-linking (or substantially no cross-linking) allows for easy diffusion of the species into the underlayer during the exposure. As such, the species that have good EUV and/or DUV absorption properties can be integrated into the volume of the underlayer.

In an embodiment, the process 250 may continue with operation 253, which comprises cross-linking polymer chains and/or reactive organic moieties in the underlayer. In an embodiment, the cross-linking of the polymer chains and/or reactive organic moieties entraps atoms and/or species of the inert gas in the underlayer. That is, after the cross-linking operation, the atoms and/or species can no longer easily outgas from the underlayer. In an embodiment, the cross-linking process is implemented while the underlayer is still exposed to the high pressure inert gas environment, or the cross-linking process is implemented shortly after removal from the high pressure inert gas environment (e.g., within 10 minutes, within 5 minutes, within 1 minute, or within 30 seconds).

In an embodiment, the cross-linking may be initiated with any suitable stimulus. In one embodiment, the cross-linking may be initiated by a thermal anneal. For example, bringing the underlayer up to a temperature between approximately 150° C. and approximately 200° C. may be used to thermally cross-link some epoxy-based underlayers. In other embodiments, UV exposure may be used to initiate a cross-linking reaction. Yet another embodiment may include a chemical stimulus in order to initiate a cross-linking reaction in the underlayer. In some embodiments, a pre-treatment may also be used before the cross-linking in order to speed up the cross-linking reaction and/or reduce the amount of stimulus needed to complete the reaction. For example, exposing the underlayer to an amine and/or an alcohol after diffusion, but before the cross-linking reaction, may benefit the cross-linking process.

In an embodiment, the process 250 may continue with operation 254, which comprises applying a resist layer over the underlayer. In an embodiment, the resist layer may be similar to any of the resist layers described in greater detail herein. For example, the resist layer may be a MOR, a CAR, or the like. The resist layer may be a positive tone resist or a negative tone resist. In an embodiment, the resist layer may be applied with a spin coating process, a dry deposition process, or the like.

In an embodiment, the process 250 may continue with operation 255, which comprises exposing the resist layer to radiation. For example, the resist layer may be selectively exposed to EUV and/or DUV radiation in order to form a latent image in the resist layer as a result of a solubility switch in the resist layer. In an embodiment, the EUV and/or DUV radiation exposure may result in the species entrapped in the underlayer producing secondary electrons and/or species that can diffuse up into the resist layer in order to participate in the solubility switch reaction. Since extra secondary electrons and/or species are added to the resist layer, the dose of EUV and/or DUV radiation may be decreased. This improves throughput and decreases costs.

In an embodiment, the process 250 may continue with operation 256, which comprises patterning the resist layer and the underlayer. The resist layer may be patterned with a developing solution that removes either the latent image or the unexposed region (depending on the tone of the resist). After the resist layer is developed, the pattern in the resist layer may be transferred into the underlayer with any suitable etching process (e.g., wet or dry etching). The patterned resist layer and underlayer may then be used as a mask in order to transfer the pattern into underlaying portions of the substrate using any suitable etching process.

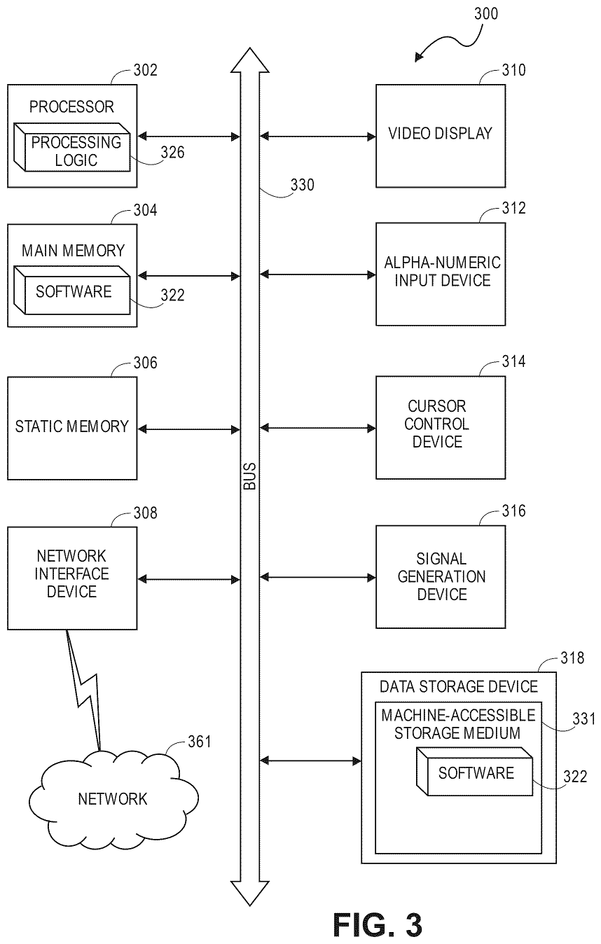

Referring now to FIG. 3, a block diagram of an exemplary computer system 300 of a processing tool is illustrated in accordance with an embodiment. In an embodiment, computer system 300 is coupled to and controls processing in the processing tool. Computer system 300 may be connected (e.g., networked) to other machines in a Local Area Network (LAN), an intranet, an extranet, or the Internet. Computer system 300 may operate in the capacity of a server or a client machine in a client-server network environment, or as a peer machine in a peer-to-peer (or distributed) network environment. Computer system 300 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 300, the term “machine” shall also be taken to include any collection of machines (e.g., computers) that individually or jointly execute a set (or multiple sets) of instructions to perform any one or more of the methodologies described herein.

Computer system 300 may include a computer program product, or software 322, having a non-transitory machine-readable medium having stored thereon instructions, which may be used to program computer system 300 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 300 includes a system processor 302, a main memory 304 (e.g., read-only memory (ROM), flash memory, dynamic random access memory (DRAM) such as synchronous DRAM (SDRAM) or Rambus DRAM (RDRAM), etc.), a static memory 306 (e.g., flash memory, static random access memory (SRAM), etc.), and a secondary memory 318 (e.g., a data storage device), which communicate with each other via a bus 330.

System processor 302 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 302 may also be one or more special-purpose processing devices such as an application specific integrated circuit (ASIC), a field programmable gate array (FPGA), a digital signal system processor (DSP), network system processor, or the like. System processor 302 is configured to execute the processing logic 326 for performing the operations described herein.

The computer system 300 may further include a system network interface device 308 for communicating with other devices or machines. The computer system 300 may also include a video display unit 310 (e.g., a liquid crystal display (LCD), a light emitting diode display (LED), or a cathode ray tube (CRT)), an alphanumeric input device 312 (e.g., a keyboard), a cursor control device 314 (e.g., a mouse), and a signal generation device 316 (e.g., a speaker).

The secondary memory 318 may include a machine-accessible storage medium 331 (or more specifically a computer-readable storage medium) on which is stored one or more sets of instructions (e.g., software 322) embodying any one or more of the methodologies or functions described herein. The software 322 may also reside, completely or at least partially, within the main memory 304 and/or within the system processor 302 during execution thereof by the computer system 300, the main memory 304 and the system processor 302 also constituting machine-readable storage media. The software 322 may further be transmitted or received over a network 361 via the system network interface device 308. In an embodiment, the network interface device 308 may operate using RF coupling, optical coupling, acoustic coupling, or inductive coupling.

While the machine-accessible storage medium 331 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of treating an underlayer for a photoresist, wherein the underlayer comprises reactive organic moieties, the method comprising:
exposing the underlayer to an environment comprising a species that has a molar absorption coefficient for extreme ultraviolet (EUV) radiation that is 0.5×10⁷ cm²/mol or higher, wherein the species diffuses into the underlayer; and
cross-linking polymer chains in the underlayer, wherein the species are entrapped in the underlayer.

2. The method of claim 1, wherein the species comprises a gas that does not substantially react with the underlayer.

3. The method of claim 2, wherein the species comprises one or more of xenon, SF₆, C₄F₈, or an iodo-comprising compound.

4. The method of claim 1, wherein a thermal anneal initiates the cross-linking of the underlayer.

5. The method of claim 1, wherein an ultraviolet (UV) exposure of the underlayer initiates the cross-linking of the underlayer.

6. The method of claim 1, wherein a pressure of the species in the environment is one atmosphere or higher.

7. The method of claim 1, wherein the underlayer comprises a material with C—X bonds, wherein X comprises one or more of H, F, Br, Cl, glycidyl, methacrylate, vinyl benzene, divinyl benzene, or disulfide.

8. The method of claim 1, wherein the underlayer comprises a bisphenol A novolac epoxy or a poly(glycidyl methacrylate) material.

9. The method of claim 1, further comprising:
applying an amine to the underlayer after diffusing the species into the underlayer.

10. The method of claim 1, further comprising:
applying an alcohol to the underlayer after diffusing the species into the underlayer.

11. A non-transitory computer readable medium comprising instructions that, when executed by at least one processor, cause a processing tool to perform the method of claim 1.

12. A method for processing a stack comprising a photoresist layer over an underlayer, wherein the underlayer comprises reactive organic moieties, the method comprising:
exposing the underlayer to an environment comprising a species that has a molar absorption coefficient for extreme ultraviolet (EUV) radiation that is 0.5×10⁷ cm²/mol or higher, wherein the species diffuses into the underlayer;
cross-linking polymer chains in the underlayer, wherein the species is entrapped in the underlayer; and
depositing the photoresist layer over the underlayer.

13. The method of claim 12, wherein the species comprises one or more of xenon, SF₆, C₄F₈, or an iodo-comprising compound.

14. The method of claim 12, wherein the photoresist layer is a chemically amplified resist.

15. The method of claim 12, wherein the photoresist layer is a metal oxide resist.

16. The method of claim 12, wherein the molar absorption coefficient is 1.5×10⁷ cm²/mol or higher.

17. The method of claim 12, wherein a thermal anneal initiates the cross-linking of the underlayer.

18. A non-transitory computer readable medium comprising instructions that, when executed by at least one processor, cause a processing tool to perform the method of claim 12.

19. A method for treating an underlayer for a photoresist, wherein the underlayer comprises reactive organic moieties, the method comprising:
exposing the underlayer to an environment comprising a gas comprising one or more of xenon, SF₆, C₄F₈, or an iodo-comprising compound, wherein a pressure of the gas is over 1.0 atmospheres, and wherein the gas diffuses into the underlayer, and
cross-linking polymer chains in the underlayer, wherein the gas is entrapped in the underlayer.

20. A non-transitory computer readable medium comprising instructions that, when executed by at least one processor, cause a processing tool to perform the method of claim 19.
